(19) United States
(12) Patent Application Publication
(10) Pub. No.: US 2013/0269764 A1
(43) Pub. Date: Oct. 17, 2013

(54) Back Contact Work Function Modification for Increasing CZTSSe Thin Film Photovoltaic Efficiency

(71) Applicants: David Aaron Randolph Barkhouse, New York, NY (US); Tayfun Gokmen, Briarcliff Manor, NY (US); Oki Gunawan, Fair Lawn, NJ (US); Richard Alan Haight, Mahopac, NY (US)

(72) Inventors: David Aaron Randolph Barkhouse, New York, NY (US); Tayfun Gokmen, Briarcliff Manor, NY (US); Oki Gunawan, Fair Lawn, NJ (US); Richard Alan Haight, Mahopac, NY (US)

(73) Assignee: International Business Machines Corporation, Armonk, NY (US)

(21) Appl. No.: 13/445,406

(22) Filed: Apr. 12, 2012

(51) Int. Cl. H01L 31/02; H01L 31/18

(52) U.S. Cl. 136/256; 438/98; 257/E31.124

(57) ABSTRACT

Techniques for increasing conversion efficiency of thin film photovoltaic devices through back contact work function modification are provided. In one aspect, a photovoltaic device is provided having a substrate; a back contact on the substrate, wherein at least a portion of the back contact has a work function of greater than about 4.5 electron volts; an absorber layer on a side of the back contact opposite the substrate; a buffer layer on a side of the absorber layer opposite the back contact; and a top electrode on a side of the buffer layer opposite the absorber layer. The absorber layer preferably has thickness that is less than a depletion width+an accumulation width+a carrier diffusion length.

### FIELD OF THE INVENTION

The present invention relates to thin film photovoltaic devices and more particularly, to techniques for increasing conversion efficiency of thin film photovoltaic devices through back contact workfunction modification.

### BACKGROUND OF THE INVENTION

Solar technology is a viable alternative to traditional energy sources. Energy produced by solar technology can generate a savings both in terms of costs and in its impact on the environment.

Thin film photovoltaics have been the focus of current research. Thin film photovoltaic devices offer advantages over their traditional photovoltaic panel counterparts in terms of manufacturing costs, versatility, etc. However, wide spread commercialization of thin film photovoltaics for energy production would require increasing their conversion efficiency.

Accordingly, techniques for improving the efficiency of thin film photovoltaic devices would be desirable.

### SUMMARY OF THE INVENTION

The present invention provides techniques for increasing conversion efficiency of thin film photovoltaic devices through back contact work function modification. In one aspect of the invention, a photovoltaic device is provided. The photovoltaic device includes a substrate; a back contact on the substrate, wherein at least a portion of the back contact has a work function of greater than about 4.5 electron volts; an absorber layer on a side of the back contact opposite the substrate; a buffer layer on a side of the absorber layer opposite the back contact; and a top electrode on a side of the buffer layer opposite the absorber layer. The absorber layer preferably has thickness that is less than a depletion width+an accumulation width+a carrier diffusion length.

In another aspect of the invention, a method of fabricating a photovoltaic device is provided. The method includes the following steps. A substrate is provided. A back contact is formed on the substrate. An absorber layer is formed on a side of the back contact opposite the substrate. A buffer layer is formed on a side of the absorber layer opposite the back contact. A top electrode is formed on a side of the buffer layer opposite the absorber layer. At least a portion of the back contact has a work function of greater than about 4.5 electron volts. The absorber layer is preferably formed on the back contact having thickness that is less than a depletion width+an accumulation width+a carrier diffusion length.

A more complete understanding of the present invention, as well as further features and advantages of the present invention, will be obtained by reference to the following detailed description and drawings.

### BRIEF DESCRIPTION OF THE DRAWINGS

FIG. 1 is a cross-sectional diagram illustrating a metal back contact having been formed on a substrate according to an embodiment of the present invention;

FIG. 2 is a cross-sectional diagram illustrating an absorber layer having been formed on the metal back contact according to an embodiment of the present invention;

FIG. 3 is a cross-sectional diagram illustrating a buffer layer having been formed on the absorber layer according to an embodiment of the present invention;

FIG. 4 is a cross-sectional diagram illustrating a top electrode having been formed on the buffer layer according to an embodiment of the present invention;

FIG. 5 is a schematic diagram of the electronic structure of a thin film photovoltaic device produced using the present techniques having an n-type buffer layer, a p-type absorber layer and a back contact with a large work function according to an embodiment of the present invention;

FIG. 6(a) is a schematic diagram showing the dependence of the total solar radiation absorbed as a function of absorber thickness and the change in open circuit voltage also with absorber thickness according to an embodiment of the present invention;

FIG. 6(b) is a graph illustrating efficiency simulation results for a back contact metal whose work function is 4.7 eV for 3 different doping levels and back contact reflectivities of 0 and 1 (no reflection and full reflection) according to an embodiment of the present invention;

FIG. 7(a) is a graph illustrating device simulations with varying absorber layer thickness and acceptor density according to an embodiment of the present invention;

FIG. 7(b) is a graph illustrating the dependence of device efficiency on the absorber layer thickness for the devices according to an embodiment of the present invention;

FIG. 7(c) is a graph illustrating the dependence of short circuit current on the absorber layer thickness for the devices according to an embodiment of the present invention;

FIG. 7(d) is a graph illustrating the open circuit voltage of the devices on absorber layer thickness according to an embodiment of the present invention;

FIG. 8 is a scanning electron micrograph (SEM) image of an absorber layer according to an embodiment of the present invention; and

FIG. 9 is a diagram illustrating use of electron beam induced current (EBIC) measurement to estimate minority carrier diffusion length according to an embodiment of the present invention.

### DETAILED DESCRIPTION OF PREFERRED EMBODIMENTS

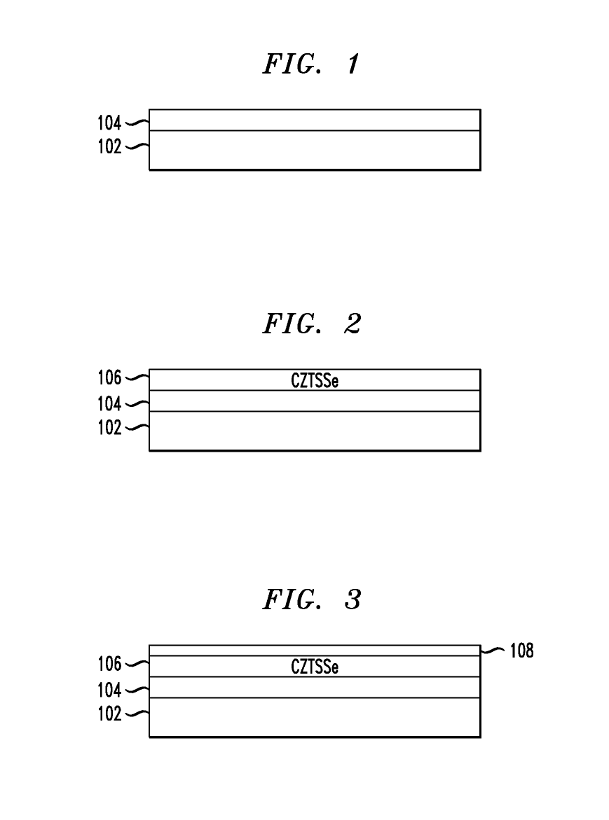

FIGS. 1-4 are diagrams illustrating an exemplary methodology for fabricating a thin film photovoltaic device having maximized efficiency. To begin the process, as shown in FIG. 1, a substrate 102 is provided. Suitable substrate materials include, but are not limited to, glass, plastic, ceramic and metal foil (e.g., aluminum, copper, etc.) substrates.

As will be described in detail below, it has been found that employing a reflective back contact on the substrate 102 aids in increasing the efficiency of the device. A reflective back contact can be created by forming the back contact, in the manner described below, on a planar substrate (glass or metal foil substrate) or on a polished substrate. Thus, it may be desirable at this stage to polish the substrate, especially in the case of a plastic or ceramic substrate. Polishing of the substrate 102 may be carried out using any mechanical or chemical mechanical process known in the art.

A back contact 104 is then formed on the substrate. During operation, back contact 104 serves to collect holes. According to the present techniques it has been found that engineering material properties and dimensions of the device component layers, including the back contact can effectively serve to increase the device efficiency. With regard to the back contact 104, this result is achieved by employing a material that (in the completed device) has a large work function Φ, e.g., a work function Φ of greater than about 4.5 electron volts (eV), for example, a work function Φ of greater than about 5.0 eV, e.g., a work function Φ of from about 5.0 eV to about 6.0 eV.

The back contact 104 may be formed from a metal or a semiconductor material. During fabrication of the device, particularly in the case of CZTSSe devices (see below), solution phase deposition on the back contact followed by high temperature anneals can result in the formation of a metal selenide or metal sulfide between the back contact and the CZTSSe. Under those circumstances the work function of the back contact is modified and hence appropriate starting back contact materials should be chosen such that the selenized or sulfurized forms possesses a large work function. The terms “metal selenide” and “metal sulfide” as used herein refer to the result of selenization/sulfurization, respectively, of both metal and semiconductor back contact materials.

By way of example only, in conventional approaches, molybdenum (Mo) is often employed as a back contact material. During formation of a CZTSSe absorber layer on a Mo-coated substrate, molybdenum selenide (MoSe₂) is typically formed. The work function Φ of MoSe₂, i.e., about 4.4 eV, is lower than the above-specified work function range and thus metal back contact materials other than Mo need to be considered for the present techniques. In conventional schemes the back contact is generally a metal chosen to provide an ohmic contact to the absorber so as to minimize series resistance associated with hole transfer from the absorber. Typically, the work function of this material (typically Mo) is not a consideration once an ohmic contact has been achieved and hence its contribution to increasing open circuit voltage (Voc) and hence efficiency has not been exploited.

By contrast, with the present techniques, the work function of the back contact is an important consideration. The back contact 104 having the proper work function (i.e., a work function Φ of greater than about 4.5 eV, for example, a work function Φ of greater than about 5.0 eV, e.g., a work function Φ of from about 5.0 eV to about 6.0 eV, see above) can be achieved in a number of different ways, depending for instance on the material being used to form the back contact 104. In general, a metal or a semiconductor material can be deposited on the substrate to form the back contact 104. When the metal is a reactive element, a pre-selenization or pre-sulfurization step may be performed (see below) to convert a top portion of the back contact 104 into a metal-selenide/metal-sulfide semiconductor. As described above, the formation of a metal-selenide/metal-sulfide semiconductor can occur during the absorber layer formation process. Thus, the use of a pre-selenization or pre-sulfurization step is optional. However, pre-selenizing or pre-sulfurizing prior to the formation of the absorber layer permits the use of temperatures greater than what might be employed during absorber layer formation (i.e., temperatures higher than what would cause decomposition of the absorber material). Without being bound by any particular theory, it is thought that the use of higher temperatures can be correlated with a higher workfunction metal-selenide/metal-sulfide semiconductor being formed. Thus, in that case, the use of a pre-selenization or pre-sulfurization step may be used to achieve a higher workfunction material.

Exemplary suitable materials for forming the back contact 104 (i.e., materials that have a proper workfunction Φ of greater than about 4.5 eV, for example, a work function Φ of greater than about 5.0 eV, e.g., a work function Φ of from about 5.0 eV to about 6.0 eV, see above) include, but are not limited to, materials selected from the group consisting of platinum (Pt), gold (Au) and selenides and/or sulfides of the following metals: vanadium (V), tantalum (Ta), niobium (Nb), tin (Sn), tungsten (W), zirconium (Zr), titanium (Ti), hafnium (Hf), gallium (Ga), indium (In), and aluminum (Al). By way of example only, suitable workfunction materials for forming the back contact include, but are not limited to Pt, Au, V(S/Se), Ta(S/Se), Nb(S/Se), Sn(S/Se), W(S/Se), Zr(S/Se), Ti(S/Se), Hf(S/Se), Ga(S/Se), In(S/Se) and Al(S/Se). The designation (S/Se) as used herein is meant to refer to the whole family of compounds with an S/(S+Se) molar ratio of from 0 to 1.

As provided above, the back contact 104 may be formed by simply depositing any of these metals or metal-selenide/sulfide semiconductor materials onto the substrate 102. The metals such as Pt and Au will not react with the absorber components during absorber layer formation. It is notable however that elements may diffuse into these materials forming alloys or just mixtures.

Alternatively, as provided above, in the case where reactive metals are being employed, a pre-selenization/sulfurization and/or reaction during the absorber layer formation can be used to convert a portion of the back contact to a metal selenide/sulfide semiconductor material. In this case, a metal such as Nb, Sn, W, Hf or Al can be deposited onto the substrate and by way of pre-selenization/sulfurization and/or reaction during the absorber layer formation a portion of the deposited metal can be converted to a metal selenide/sulfide, e.g., NbSe₂/NbS₂, SnSe₂/SnS₂, WSe₂/WS₂, HfSe₂/HfS₂, AlSe₂/AlS₂, respectively. It is notable that the deposited metal in this case might not have the appropriate workfunction. However, the resulting selenide/sulfide does. Further, as provided above, it is thought that the higher temperatures employable during a pre-selenization/sulfurization step might result in a higher workfunction as compared to the lower temperatures used during absorber formation. Thus, in some instances, the pre-selenization/pre-sulfurization step might be needed to achieve the appropriate work function. In other cases, an appropriate workfunction may be achieved with either a pre-selenization/sulfurization step or during absorber formation, however a (desirably) higher workfunction may be achieved using the optional pre-selenization/sulfurization. It is also notable that when it is described herein that the back contact has an appropriate workfunction it is meant that at least a portion of the back contact 104 has a workfunction according to the values provided above. Accordingly, any of the above-listed materials, as-deposited, would result in a back contact 104 having an appropriate workfunction. When a portion of the as-deposited contact material is converted to a metal selenide/silicide (as described above) it may be the case that only the metal selenide/silicide portion of the contact has the appropriate workfunction. This is considered herein to be a back contact having the appropriate workfunction.

According to an exemplary embodiment, the back contact 104 is formed by depositing the respective material (metal or semiconductor material, see above) onto the substrate 102 using evaporation or an electroplating process to a thickness of from about 0.1 nm to about 1,000 nm, e.g., from about 10 nm to about 500 nm. As provided above, depending on the material employed, a portion of the back contact 104 may be converted to a metal selenide/silicide. Thus at least a portion of the metal back contact 104 formed as described herein will have a work function Φ of greater than about 4.5 eV, for example, a work function Φ of greater than about 5.0 eV, e.g., a work function Φ of from about 5.0 eV to about 6.0 eV.

Alternatively, for devices deposited on foils or other flexible substrates the back contact 104 could serve as the substrate itself. The same requirements regarding the workfunction of the back contact (or at least a portion thereof) would also apply in this case, and the above-described back contact materials would be suitable, and could be formed (deposited) in the same manner as described above. However, in order to provide some structural rigidity (since a separate substrate will not be employed), the back contact should, in this case, be thicker. By way of example only, when the back contact also serves as a substrate for the device, the back contact preferably has a thickness of from about 0.5 millimeter (mm) to about 10 mm, e.g., from about 1 mm to about 5 mm.

Further, with conventional thin film photovoltaic device fabrication techniques it is often considered desirable to introduce rough interfaces by roughening substrate and/or reflectors at the back side so as to scatter light into the absorber material. See, for example, Hupkes et al., “Light Scattering and Trapping in Different Thin Film Photovoltaic Devices,” 24^{th} European Photovoltaic Solar Energy Conference, 21-25 September 2009, Hamburg, Germany (hereinafter “Hupkes”), the contents of which are incorporated by reference herein. In Hupkes it is described that the roughening can be achieved using plasma texturing texture etching, etc.

However, it has been found, by way of the present techniques that in fact employing a non-textured, reflective back contact serves to increase the efficiency of the device. As provided above, a reflective back contact can be achieved through deposition of the contact materials onto already polished and/or planar substrates (glass or metal). The specific reflectivity of the back contact is a fundamental property of the deposited material but by way of example only is preferably in the range of solar wavelengths, e.g., the reflectivity of the back contact is from about 0.6 to about 0.95. See, for example, CRC Handbook of Physics, 68^{th} edition 1987-1988, pages E377-E392, the contents of which are incorporated by reference herein. Reflectivity or “R” ranges from 0 to 1 so that something that has a R=0.5 means that 50 percent (%) of the incident light intensity is reflected. In order to increase the reflected light path length in the absorber, the back surface can be structured so as to reflect the light in non-normal directions, e.g., as is the case in Hupkes wherein the spatial periodicity is larger than the wavelengths of solar radiation. However, if the periodicity is smaller than the wavelengths of solar radiation, then the light will diffract or scatter and may reflect multiple times off the back contact thus (undesirably) reducing the amount of light reflected back into the absorber. Hupkes refers to enhanced light trapping leading primarily to enhanced short circuit current (Jsc). By comparison, the present techniques look to enhance Voc.

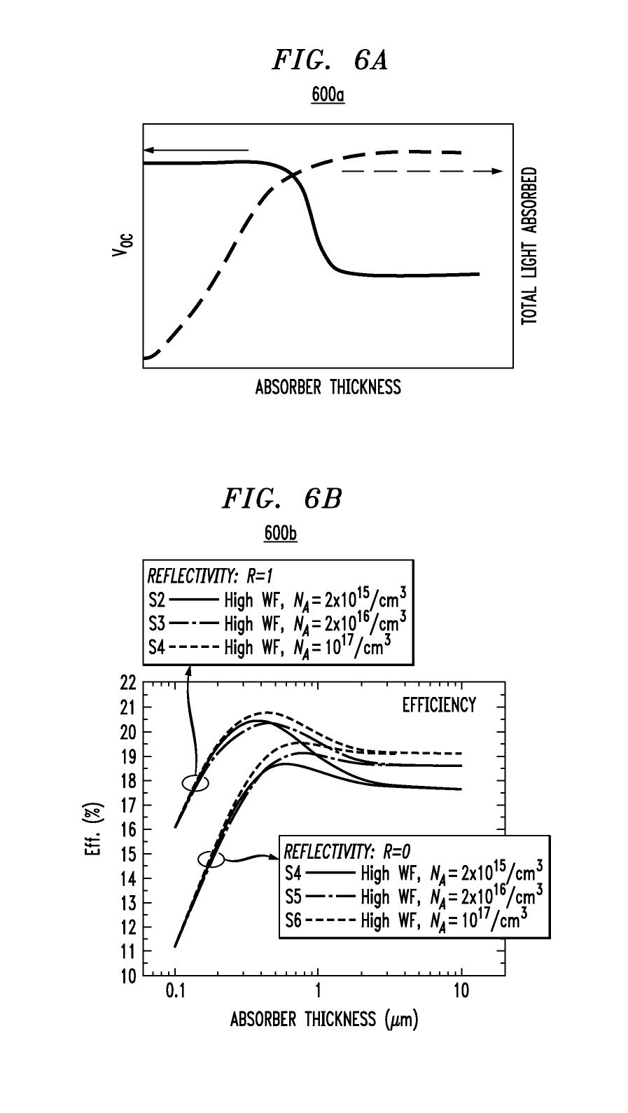

It is notable that in the figures and description below, the values of zero (0) reflectivity and one (1) reflectivity are used. The use of 0 reflectivity (no reflection) and a reflectivity of 1 (full reflection) is just a means of looking at the extremes. A reflectivity of 1 would correspond to, for example, aluminum. A comparison of samples with back contacts having no reflectivity and complete reflectivity are compared in FIG. 6, described below. According to an exemplary embodiment, the back contact formed according to the techniques presented herein has a high reflectivity in the wavelengths of from about 400 nanometers (nm) to about 1,200 nm. High reflectivity means R is from about 0.7 to about 0.95 (see above description of reflectivity).

Next, an absorber layer 106 is formed on the metal back contact 104. See FIG. 2. According to an exemplary embodiment, the absorber layer 106 is formed from a p-type, semiconducting chalcogenide material containing copper (Cu), zinc (Zn) and tin (Sn) and at least one of sulfur (S) and selenium (Se). This chalcogenide material is abbreviated herein as CZTSSe. With regard to S and Se, the absorber layer can contain S alone, Se alone or a combination of S and Se. During operation, the absorber layer 106 generates a population of electrons and holes (electron hole pairs) when exposed to solar radiation.

According to an exemplary embodiment, the absorber layer 106 is formed using a solution-based approach. Suitable solution-based approaches for forming a CZTSSe absorber layer are described for example in U.S. patent application Ser. No. 13/207,269, filed by Bag et al., entitled “Capping Layers for Improved Crystallization” (hereinafter “Bag”), U.S. patent application Ser. No. 13/207,248, filed by Mitzi et al., entitled “Process for Preparation of Elemental Chalcogen Solutions and Method of Employing Said Solutions in Preparation of Kesterite Films” (hereinafter “Mitzi '248”), and U.S. patent application Ser. No. 13/207,187 filed by Mitzi et al., entitled “Particle-Based Precursor Formation Method and Photovoltaic Device Thereof” (hereinafter “Mitzi '187”), the entire contents of each of which are incorporated by reference herein.

With a solution-based approach to CZTSSe absorber layer formation, the absorber layer (Cu, Zn, Sn and S and/or Se) components (dissolved or dispersed in a solvent such as hydrazine or a hydrazine-water mixture, see for example Bag) are deposited on the metal back contact using a suitable deposition process such as, but not limited to, solution coating, evaporation, electrochemical deposition and sputtering. An anneal is then performed to intersperse the elements throughout the layer thus increasing the compositional uniformity of the film (see Bag). By way of example only, this anneal may be performed at a temperature of from about 300 degrees Celsius (° C.) to about 700° C., e.g., from about 400° C. to about 600° C. for a duration of from about 1 second to about 24 hours, for example, from about 20 seconds to about 2 hours, e.g., from about 1 minute to about 30 minutes.

As described above, it is during this annealing step that a metal selenide or metal sulfide may form above the metal back contact 104. This depends on the reactivity of the metal used in the back contact. See above. However, as highlighted above, the use of a pre-selenization or pre-sulfurization step permits the use of temperatures that are higher than what is suitable during absorber layer formation. Namely, the use of temperatures greater than 500° C. can result in degradation (decomposition) of the absorber layer material. Thus, any pre-selenization or pre-sulfurization would be carried out prior to forming the absorber layer 106. Further, as provided above, without being bound by any particular theory, it is thought that use of higher temperatures during a pre-selenization or pre-sulfurization will result in the formation of a higher workfunction material.

According to an exemplary embodiment, this (optional) pre-selenization or pre-sulfurization step is performed by heating the substrate 102 and back contact 104 in the presence of a selenium or sulfur-containing vapor. By way of example only, the substrate 102 and back contact 104 are placed in a glove box wherein solid selenium or sulfur is heated next to the substrate 102/back contact 104. In one exemplary embodiment, the heating occurs on a hot plate but could be performed in the same manner using any of a number of methods such as an oven or furnace. Alternatively, the Se or S can also be introduced to the glove box as a gas, e.g., H₂S or H₂Se. In either case, the heating is performed at a temperature of greater than about 350° C., for example from about 400° C. to about 700° C., for a duration of from about 30 seconds to about 1 hour (but longer durations can be employed).

This pre-selenization/pre-sulfurization step results in a portion of the back contact 104 being converted to a selenide and/or sulfide. The amount of the back contact 104 that is converted to a selenide and/or sulfide depends on the processing conditions. For instance, increasing/decreasing the duration that the substrate and back contact are heated in the presence of the selenium and/or sulfur-containing vapor (see above) will serve to increase/decrease the thickness of the metal selenide and/or sulfide layer. It is possible to convert the entire back contact 104 into a selenide and/or sulfide. However, according to an exemplary embodiment, only a top portion (the top less than 500 nm, e.g., the top from about 50 nm to about 400 nm) of the back contact is converted to a metal selenide or metal sulfide. This is also the case when, for instance, the conversion of a portion of the back contact metal occurs during the absorber layer formation. Namely, during the absorber layer formation, the top less than 500 nm, e.g., the top from about 50 nm to about 400 nm of the back contact is converted to a metal selenide or metal sulfide.

In order to achieve maximum device efficiency, in addition to use of the large work function back contact 104, as described above, the configuration of the absorber layer (to be formed on the back contact, see below) has to be such that the its thickness is great enough to serve as an absorber, however the absorber layer thickness should not be larger than the combined depletion width, accumulation width and carrier diffusion length. This aspect will be described in detail below.

A CZTSSe absorber material is naturally p-doped due to intrinsic defects, and thus behaves as a p-type semiconductor. If the doping is light, then the depletion fields extend further into the CZTSSe and allow the absorber to be slightly thicker. For higher doping levels the depletion length is shorter so the absorber has to be thinner to see the effect of the increased work function on Voc. Examples involving different absorber layer doping levels are provided and described below. In those examples, the varying doping levels are meant to represent intrinsic p-type doping levels that may (naturally) occur in these CZTSSe materials, and no intentional doping is being performed.

Next, as shown in FIG. 3, a buffer layer 108 is formed on the absorber layer. According to an exemplary embodiment, the buffer layer 108 is formed from an n-type, semiconducting material including, but not limited to, zinc sulfide (ZnS), cadmium sulfide (CdS), indium sulfide (InS), oxides thereof and/or selenides thereof Accordingly, a p-n heterostructure is formed with the p-type absorber layer and the n-type buffer layer. By way of example only, the buffer layer 108 may be formed by depositing the respective buffer layer material on the absorber layer using vacuum evaporation, chemical bath deposition, electrochemical deposition, atomic layer deposition, successive ionic layer absorption and reaction (SILAR), chemical vapor deposition, sputtering, spin coating, doctor blading or physical vapor deposition to a thickness of from about 1 nm to about 1,000 nm. During operation, the buffer layer 108 serves to collect electrons.

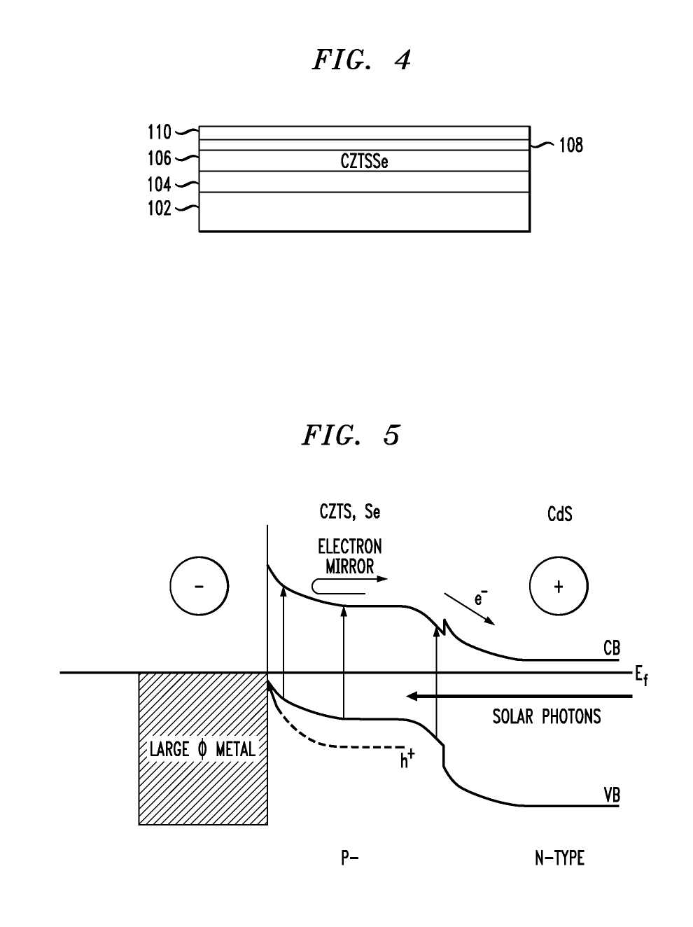

A top electrode 110 is then formed on the buffer layer 108. See FIG. 4. According to an exemplary embodiment, the top electrode 110 is formed from a transparent conductive material, such as doped zinc oxide (ZnO), indium-tin-oxide (ITO), doped tin oxide or carbon nanotubes. The techniques for forming a tope electrode from these materials would be apparent to one of skill in the art and thus are not described further herein.

100451 FIG. 5 is a diagram illustrating a schematic of the electronic structure of a thin film photovoltaic device produced using the above-described techniques, having an n-type buffer layer, a p-type absorber layer and a back contact with a large work function. In FIG. 5, CZTS, Se is the absorber material in the photovoltaic device, W_{dep} is depletion width in the absorber CZTS,Se, W_{accum} is accumulation width in the absorber CZTS,Se, L_{diffusion} is diffusion length in the absorber, W_{CZTS} is total width of absorber and Φ is work function of the back contact material.

Equilibration of the Fermi levels of the metal back contact with the p-n heterostructure (the p-type absorber layer and the n-type buffer layer, see above, which create a heterojunction) results in transfer of electronic charge to the metal contact. This creates an electrostatic potential that attracts holes and repels electrons (electron mirror). The existence of this electrostatic potential produces fields which bend the absorber bands upward at the metal contact (accumulation) and downward at the p-n junction formed between the absorber and the buffer (depletion). Here depletion corresponds to the case where the electrostatic field at the heterojunction accelerates the majority carrier holes away from the interface. The accumulated back region corresponds to the case where the electrostatic field attracts holes to the metal/semiconductor interface.

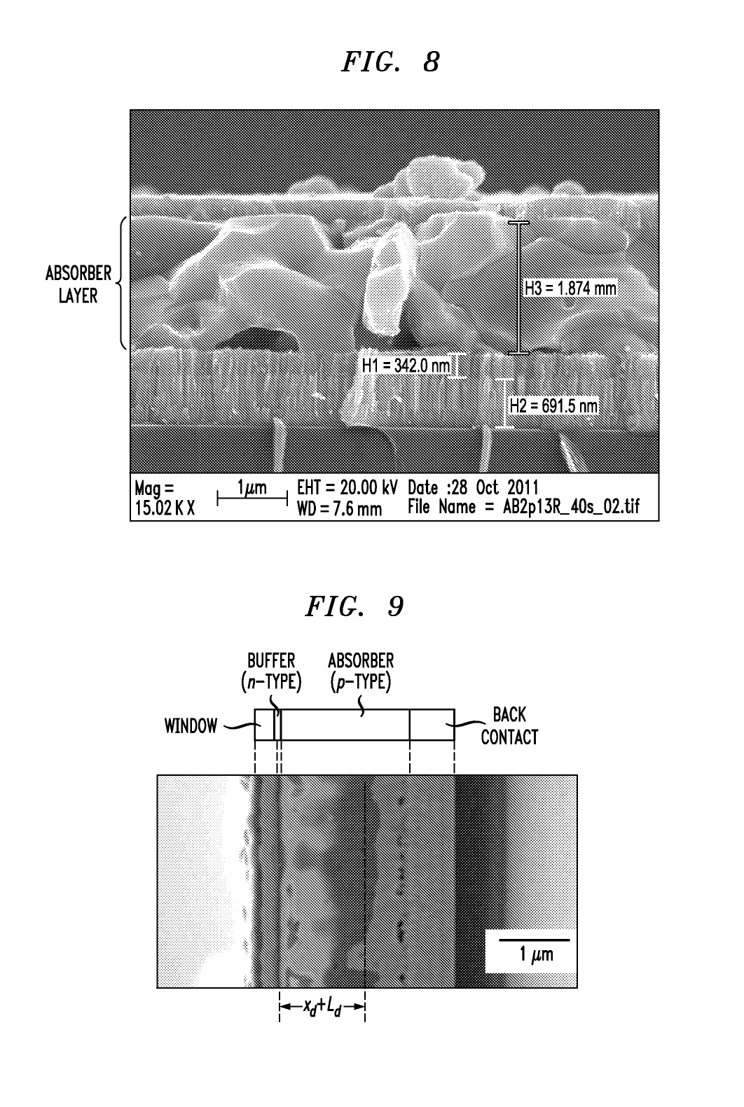

There are two cases to consider. In the first case, the total absorber thickness (i.e., the thickness of the absorber layer 106, see also FIG. 8, described below)<depletion width+minority carrier diffusion length+accumulation width. Here photoexcited electrons anywhere within the absorber are swept toward the absorber/buffer contact and holes are swept to the absorber/metal contact. Here V_{oc} of the device is increased by the band bending in the accumulated region.

100481 By contrast, with conventional thin film photovoltaic devices, typically total absorber thickness>depletion width+minority carrier diffusion length+accumulation width and an accumulation region may not even exist. Here, electrons that are generated in the central region of the absorber diffuse randomly. Even though the electrons that make it into the depletion region are swept to the front absorber/buffer interface due to the electric field and are collected, the majority of electrons may recombine with the holes in the absorber or at the back contact without contributing to the current. As a consequence, the increase of V_{oc} is dramatically reduced.

The depletion region forms in a p-n junction where the mobile charge carriers have diffused away, or have been forced away by an electric field. What remains in the depletion region are ionized donor or acceptor impurities (acceptor impurities for the present case). The depletion width x_{d} for a single sided junction is therefore determined by the concentration of these ionized impurities in the absorber layer by

$${x}_{d} = \sqrt{\frac{2 {ɛ}_{r} {ɛ}_{0}}{q} \frac{( {V}_{hi} - V )}{{N}_{A}}} ,$$

where εᵣ is the dielectric constant of the absorber material, ε₀ is permitivity in vacuum, q is the electron charge, N_{A} is the impurity concentration, V_{bi} is the built in potential in the junction and V is the external voltage applied to the junction. The depletion width can be easily measured by performing capacitance versus voltage measurements. In the present case, the depletion width can vary from about 0.1 micrometers to about 1 micrometer depending on the impurity concentration.

The minority carrier diffusion length is the average length a carrier moves between generation and recombination. The minority carrier diffusion length L_{d} is therefore related to the carrier mobility (μ) and lifetime (τ) by the equation

$${L}_{d} = \sqrt{\frac{kT}{q} μ τ}$$

wherein T is temperature, k is the Boltzmann constant and q is the electron charge. The minority carrier diffusion length can be deduced by simply performing voltage dependent external quantum efficiency measurements. In the present case, L_{d} can vary from about 0.1 micrometers to about 1 micrometers. A direct way to estimate the minority carrier diffusion length is described in conjunction with the description of FIG. 9, below.

The accumulation region width forming at the back contact would be determined by the amount of bending caused by the work function of the back contact. However, as the name implies, in the accumulation region the majority carrier concentration (holes for the present case) is larger compared to the interior of the material well away from the front and back surfaces and therefore screens the electrostatic potentials very strongly resulting in very small accumulation region widths. In the present case, the accumulation widths are smaller than about 0.1 micrometers and are therefore negligible as compared to x_{d} and L_{d}.

Thus a second criterion is established for device optimization: the thickness of the absorber layer should correspond to the first case (see above) where the absorber thickness is minimized. In this regard, the absorber layer thickness should be optimized to a minimum absorber thickness sufficient to efficiently absorb the incoming solar radiation. However, as the absorber layer is made thinner, the field at the back contact/absorber becomes more effective but less light is being absorbed. Therefore there is an optimal region of thickness and back contact work function that maximizes the device efficiency and depends upon the details of the absorber such as absorption coefficient, dielectric constant and diffusion length/carrier mobility.

By way of example only, given the material properties such as doping density (which determines x_{d}), L_{d}, dielectric constant, absorption coefficient as function of wavelength, device simulation can be performed to obtain the optimum absorber layer thickness. However, it is known that the optimum absorber layer thickness happens below x_{d}+L_{d} (because of the increase in Voc) and above a characteristic absorption length where the reduction in Jsc is not prominent. This characteristic absorption length would depend on the details of the absorption coefficient and also the reflectivity of the back contact. Since for the R=1 example light makes two passes through the absorber layer, the peak efficiency is observed at smaller layer thicknesses as shown in FIG. 6(a) and FIG. 6(b).

FIG. 6(a) is a schematic diagram showing the dependence of the total solar radiation absorbed as a function of absorber thickness (hatched curve) and the change in open circuit voltage Voc also with absorber thickness (solid curve). The total absorbed light starts at 0 for 0 thickness and increases to an asymptotic level at large thickness which corresponds to the maximum amount of light that can be absorbed independent of increased thickness. For Voc, the maximum Voc achievable is at 0 absorber thickness and decreases when the sum of the depletion+accumulation+electron diffusion lengths>the absorber thickness. The fold of these two curves gives rise to the peak in efficiency for a back contact of a given work function and an absorber of corresponding dielectric constant and doping level.

Simulations of this optimization have been carried out and are shown in FIG. 6(b). FIG. 6(b) is a graph 600b illustrating efficiency simulation results for a back contact metal whose work function is 4.7 eV for 3 different doping levels N, (10¹⁵10¹⁶ and 10¹⁷) (see above explanation regarding intrinsic p-type doping levels of a CZTSSe absorber material) N_{A} of absorber and back contact reflectivities R of 0 and 1 (no reflection and full reflection).

In graph 600b, absorber thickness, measured in micrometers (μm) is plotted on the x-axis and percent efficiency (Eff (%)) is plotted on the y-axis. As can be seen, the simulation results shown in FIG. 6(b) confirm that there is an optimal absorber thickness that must be achieved for a given back contact work function, to achieve the increase in efficiency.

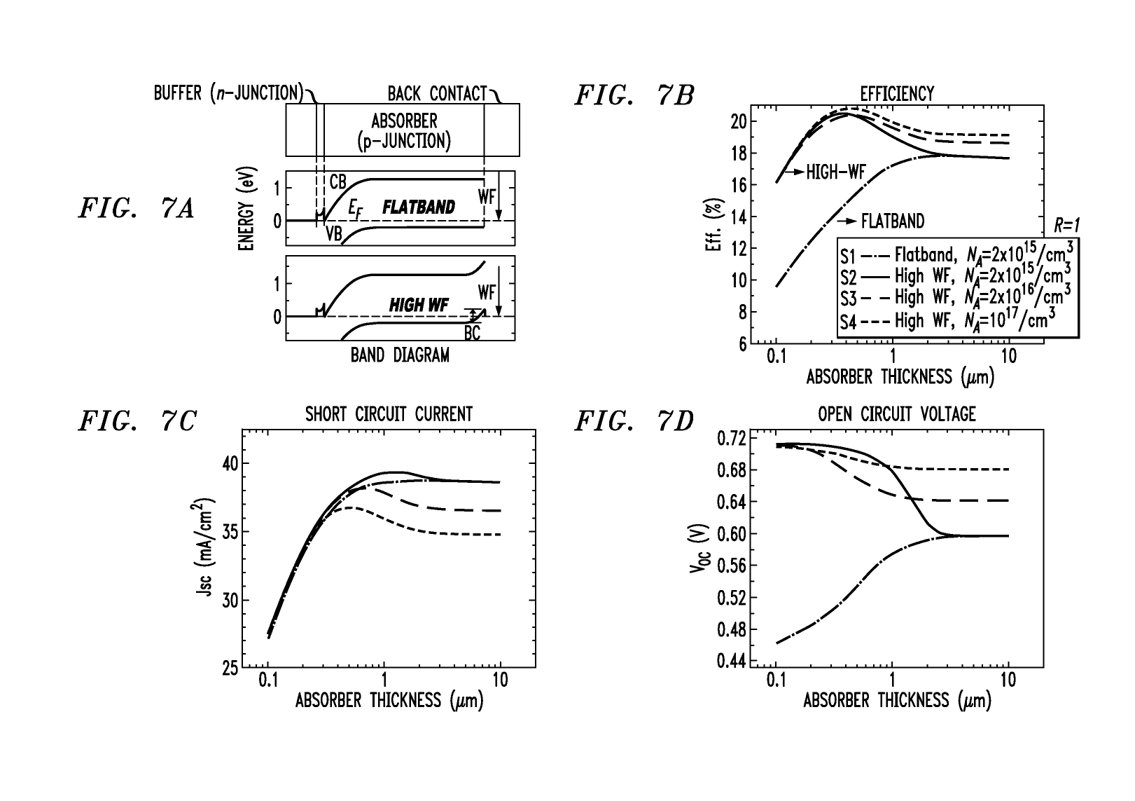

FIGS. 7A-D are graphs 700A-D, respectively, illustrating a simulation on the impact of the back contact to the device performance for two cases: Flatband (see FIG. 7(a) where there is no band bending, i.e., the bands are literally flat) and accumulation back contact (see FIG. 1a where the bands are bending up at the back contact). The device parameters are absorber layer thickness W, depletion width x_{d}, minority carrier diffusion length L_{d}, and acceptor density Na. Acceptor density represents the doping density (of p-type impurities) in the absorber which, as described above, determines the depletion width x_{d}.

Device simulations were performed using wxAMPS program (see Y. Liu et al., “A new simulation software of solar cells-wxAMPS,” Solar Energy Materials and Solar Cells, 98, pgs. 124-128 (2012), the contents of which are incorporated by reference herein) for two different scenarios with varying absorber layer thickness as illustrated in FIG. 7(a). consisting of Flatband condition: S1 and High Work function (High WF) condition: S2, S3, S4. These scenarios include: 1. S1: Device with a flat band condition at the back contact and with N_{A}=2e15/cm³, 2. S2: Device with a high work function back contact and N_{A}=2e15/cm³, 3. S3: Device with a high work function back contact and N_{A}=2e16/cm³, and 4. S4: Device with a high work function back contact and N_{A}=1e17/cm³. Results on S1 and S2 are useful to compare the effect of back contact work function and the results on S2, S3 and S4 are useful to see effect of x_{d} (varied by changing N_{A}). For all cases L_{d} is fixed at a value of 720 nm. Since the band bending at the back contact is an input to the simulation, it is known that the flatband condition is for scenario S1 and the figure showing an up bending at the back contact is for the S2, S3 and S4 scenarios.

FIGS. 7(b)-(d) summarize the simulation results where the dependence of the efficiency, Jsc and Voc on the absorber layer thickness is shown for the four different scenarios described above. In FIG. 7(b), absorber thickness (measured in micrometers (μm)) is plotted on x-axis and percent efficiency (Eff. (%)) is plotted on the y-axis. For thick absorber layer devices where L_{d}+X_{d}<W (corresponding to W greater than about 2 μm), the efficiency does not show any dependence on W. This is indeed expected since the back contact is completely separated from the front of the device. However, as W is reduced below L_{d}+X_{d}, two different behaviors are observed. For a device with a flat band condition (S1) Voc drops with decreasing W, where as devices with a high work function (High WF) metal back contact (S2, S3 and S4) show an increase in Voc with decreasing W. Moreover, among these cases S2 shows the largest increase in Voc. The increase in Voc is limited by the energy difference between the Fermi energy and the valence band and therefore it is indeed expected for a device with a lower doping concentration the enhancement in Voc due to the back contact would be larger. In addition, lower doping concentrations would result in larger depletion widths and hence the increase in Voc starts to happen for larger W. Thus, the simulations confirm that a high work function metal as a back contact with a thin absorber layer is needed to observe the enhancement in Voc.

In FIG. 7(c) the dependence of short circuit current (Jsc) on W is shown. In FIG. 7(c) absorber thickness (measured in μm) is plotted on x-axis and Jsc (measured in milliamps per square centimeter (mA/cm²) is plotted on the y-axis. Jsc is influenced by the combination of light absorption and the collection efficiency of the photo-generated carriers. For a long device (long devices are devices having an absorber thickness>x_{d}+L_{d}) the collection of the carriers happens at the front of the device within the distance determined roughly by x_{d}+L_{d}. Even though, the carriers generated within depletion region are collected almost perfectly, collection of the carrier beyond the depletion region relies on diffusion of the carriers. Therefore, as the thickness of the device is reduced the recombination at the back contact starts to become important and may reduce overall the collection efficiency. This is indeed why S1 shows a monotonic decrease with decreasing absorber layer thickness. However, in contrast to S1, Jsc for S2, S3 and S4 first show an increase and then a decrease as W reduced. The increase in Jsc for moderate thicknesses is due the increase in the overall collection efficiency due to the back surface field introduced by the high work function back contact (see FIG. 7(a)). This back surface field helps the collection of the electrons that are generated even very close to the back contact. Therefore, it is important to have a high work function metal at the back side of the device to have a boost in Jsc for short devices (short devices are devices having an absorber thickness<x_{d}+L_{d}). The unavoidable decrease in Jsc for very short devices is because of the reduction in absorbed light due to insufficient absorber material. The reflective back contact would be helpful to reduce this undesirable reduction in absorbed light and therefore it is an important criteria during the selection of the back contact material. It is assumed that the back contact is a perfect reflector with reflectivity R=1 for the simulations reported above.

In FIG. 7(d) the dependence of open circuit voltage Voc on the absorber layer thickness is presented. In FIG. 7(d) absorber thickness (measured in μm) is plotted on x-axis and Voc (measured in volts (V)) is plotted on the y-axis. Efficiency would have the individual contributions coming from Voc and Jsc as discussed above. It is clear that the efficiency is larger for devices with high work function back contact compared to the flat band condition. FIG. 7(d) also shows that there is an optimum absorber thickness, which is from about 0.4 μm to about 0.5 μm, where the efficiency of the overall device has a maximum.

FIG. 8 is a scanning electron micrograph (SEM) image of an absorber layer that is representative of absorber layer 106, see above. FIG. 8 illustrates how the thickness of the absorber layer can be measured. In the example shown in FIG. 8, the absorber layer has a thickness of 1,874 micrometers.

FIG. 9 is a diagram illustrating use of electron beam induced current (EBIC) measurement to estimate minority carrier diffusion length. A direct way to estimate the minority carrier diffusion length in the solar cell is to perform an EBIC measurement. Here, a cross-section of the device is taken, an electron beam is irradiated across the cell and the photocurrent is measured. The measurement is performed using modified scanning electron microscope. The region of high current intensity indicates the region of effective minority carrier collection: x_{d}+Ld. Thus by measuring x_{d} using capacitance measurement above Ld can be estimated.

Although illustrative embodiments of the present invention have been described herein, it is to be understood that the invention is not limited to those precise embodiments, and that various other changes and modifications may be made by one skilled in the art without departing from the scope of the invention.

What is claimed is:

1. A photovoltaic device, comprising:
a substrate;
a back contact on the substrate, wherein at least a portion of the back contact has a work function of greater than about 4.5 electron volts;
an absorber layer on a side of the back contact opposite the substrate;
a buffer layer on a side of the absorber layer opposite the back contact; and
a top electrode on a side of the buffer layer opposite the absorber layer.

2. The photovoltaic device of claim 1, wherein the at least a portion of the back contact has a work function of greater than about 5.0 electron volts.

3. The photovoltaic device of claim 1, wherein the at least a portion of the back contact has a work function of from about 5.0 electron volts to about 6.0 electron volts.

4. The photovoltaic device of claim 1, wherein the substrate comprises a glass, plastic, ceramic or a metal foil substrate.

5. The photovoltaic device of claim 1, wherein the back contact has a thickness of from about 0.1 nm to about 1,000 nm.

6. The photovoltaic device of claim 1, wherein the back contact comprises a material selected from the group consisting of Pt, Au, V(S/Se), Ta(S/Se), Nb(S/Se), Sn(S/Se), W(S/Se), Zr(S/Se), Ti(S/Se), Hf(S/Se), Ga(S/Se), In(S/Se) and Al(S/Se).

7. The photovoltaic device of claim 1, wherein the absorber layer comprises a p-type semiconducting material.

8. The photovoltaic device of claim 1, wherein the absorber layer comprises a chalcogenide material containing Cu, Zn, Sn and at least one of S and Se.

9. The photovoltaic device of claim 1, wherein the absorber layer has thickness that is less than a depletion width+an accumulation width+a carrier diffusion length.

10. The photovoltaic device of claim 1, wherein the buffer layer has a thickness of from about 1 nm to about 1,000 nm.

11. The photovoltaic device of claim 1, wherein the buffer layer comprises an n-type semiconducting material.

12. The photovoltaic device of claim 1, wherein the buffer layer comprises a semiconducting material selected from the group consisting of zinc sulfide (ZnS), cadmium sulfide (CdS), indium sulfide (InS), oxides thereof and/or selenides thereof.

13. The photovoltaic device of claim 1, wherein the top electrode comprises a transparent conductive material selected from the group consisting of doped zinc oxide (ZnO), indium-tin-oxide (ITO), doped tin oxide and carbon nanotubes.

14. A method of fabricating a photovoltaic device, comprising the steps of:
providing a substrate;
forming a back contact on the substrate,
forming an absorber layer on a side of the back contact opposite the substrate;
forming a buffer layer on a side of the absorber layer opposite the back contact; and
forming a top electrode on a side of the buffer layer opposite the absorber layer, wherein at least a portion of the back contact has a work function of greater than about 4.5 electron volts.

15. The method of claim 14, wherein at least a portion of the back contact has a work function of greater than about 5.0 electron volts.

16. The method of claim 14, wherein at least a portion of the back contact has a work function of from about 5.0 electron volts to about 6.0 electron volts.

17. The method of claim 14, wherein the back contact is formed on the substrate using evaporation or an electroplating process.

18. The method of claim 14, further comprising the step of pre-selenizing or pre-sulfurizing the back contact.

19. The method of claim 18, wherein the step of pre-selenizing or pre-sulfurizing the back contact comprises the step of:
heating the back contact in the presence of a selenium-containing vapor or a sulfur-containing vapor at a temperature of from about 400° C. to about 700° C., for a duration of from 30 seconds to about 1 hour.

20. The method of claim 14, wherein the absorber layer is formed on the back contact using a solution-based deposition process.

21. The method of claim 14, wherein the absorber layer is formed on the back contact, with the absorber layer having thickness that is less than a depletion width+minority carrier diffusion length+accumulation width.

22. The method of claim 14, wherein the buffer layer is formed on the absorber layer using vacuum evaporation, chemical bath deposition, electrochemical deposition, atomic layer deposition, successive ionic layer absorption and reaction (SILAR), chemical vapor deposition, sputtering, spin coating, doctor blading or physical vapor deposition.

23. The method of claim 14, wherein the back contact comprises a material selected from the group consisting of Pt, Au, V(S/Se), Ta(S/Se), Nb(S/Se), Sn(S/Se), W(S/Se), Zr(S/Se), Ti(S/Se), Hf(S/Se), Ga(S/Se), In(S/Se) and Al(S/Se).

24. A photovoltaic device, comprising:
a substrate;
a back contact on the substrate, wherein at least a portion of the back contact has a work function of greater than about 4.5 electron volts;
an absorber layer on a side of the back contact opposite the substrate, wherein the absorber layer has thickness that is less than a depletion width+an accumulation width+a carrier diffusion length;
a buffer layer on a side of the absorber layer opposite the back contact; and
a top electrode on a side of the buffer layer opposite the absorber layer.
